(19) United States
(12) Patent Application Publication
(10) Pub. No.: US 2016/0372634 A1
(43) Pub. Date: Dec. 22, 2016

(54) LIGHT-EMITTING DIODE PRODUCTION METHOD USING NANOSTRUCTURE TRANSFER, AND LIGHT-EMITTING DIODE OBTAINED THEREBY

(71) Applicant: POSTECH ACADEMY-INDUSTRY FOUNDATION, Pohang -si (KR)

(72) Inventors: Chul-Jong YOO, Busan (KR); Jong Lam LEE, Pohang-si (KR)

(21) Appl. No.: 15/118,079

(22) PCT Filed: Feb. 6, 2015
(86) PCT No.: PCT/KR2015/001222

§ 371 Date: Sep. 2, 2016

(30) Foreign Application Priority Data
Feb. 11, 2014 (KR) 10 2014 0015396

(51) Int. Cl. H01L 33/32; H01L 33/24

(52) U.S. Cl. CPC H01L 33/32; H01L 33/24; H01L 2933/0033

(57) ABSTRACT

A light-emitting diode having outstanding light-extraction efficiency and its production method are disclosed. A method is provided wherein a nanostructure is coated uniformly over a wide surface area by means of spherical nanostructure transfer and wherein a light-emitting diode is produced in which the light-extraction efficiency is maximized by means of the coating.

A production method for a light-emitting diode in which a first semiconductor layer, an active layer and a second semiconductor layer are formed, includes: coating a spherical nanostructure onto a first substrate; transferring the nanostructure from the first substrate, which has been coated with the nanostructure, onto a second substrate; transferring the nanostructure, which has been transferred onto the second substrate, onto the second semiconductor layer; and forming an uneven portion by dry etching the second semiconductor layer by using a mask constituted by the nanostructure which has been transferred onto the second semiconductor layer.

### BACKGROUND OF THE INVENTION

### 1. Field of the Invention

The present invention relates to a method of manufacturing a light-emitting diode using nanostructure transfer, and more particularly, to a method, in which a wide area is uniformly coated with a nanostructure by transfer of the spherical nanostructure to manufacture a light-emitting diode having maximized light extraction efficiency, and a light-emitting diode having excellent light extraction efficiency manufactured by the method.

### 2. Description of the Related Art

Since various types of high-quality lighting systems may be realized due to the fact that a white light source gallium nitride-based light-emitting diode has high energy conversion efficiency as well as long lifespan and high directivity of light, may be driven with a low voltage, does not require preheating time and complex driving circuit, and is resistant to shock and vibration, the white light source gallium nitride-based light-emitting diode is expected as a solid-state lighting source which will replace conventional light sources, such as an incandescent lamp, a fluorescent lamp, and a mercury lamp, in the near future.

However, in order for the gallium nitride-based light-emitting diode to be used as a white light source in replacement of a conventional mercury lamp or fluorescent lamp, the gallium nitride-based light-emitting diode must not only have excellent thermal stability, but must also be able to emit high-power light even at low power consumption.

A horizontal structure gallium nitride-based light-emitting diode, which is currently being widely used as a white light source, is advantageous in that manufacturing costs are relatively low and a manufacturing process is simple, but is disadvantageous in that it is inappropriate to be used as a large-area high-power light source having a high applied current.

A vertical structure light-emitting diode is a device which overcomes the disadvantage of the horizontal structure light-emitting diode and is easily applied to a large-area high-power light-emitting diode, and the vertical structure light-emitting diode has many advantages in comparison to the conventional horizontal structure device.

For example, in the vertical structure light-emitting diode, since very uniform current spreading may be obtained due to low current spreading resistance, a lower operating voltage and a high light output may be obtained. Also, since smooth heat dissipation is possible through a metal or semiconductor substrate having good thermal conductivity, longer device lifetime is achieved and significantly improved high-power operation is possible.

In the vertical structure light-emitting diode, since a maximum applied current is increased in comparison to that of the horizontal light emitting diode, it is expected that the vertical structure light-emitting diode will be widely used as a white light source for lighting.

In the manufacture of the gallium nitride-based vertical light-emitting diode, a portion that may significantly improve light output of the device is an n-type semiconductor layer on the top of the device.

However, since there is a big difference between a refractive index of the n-type semiconductor layer composed of a smooth flat surface and a refractive index of the atmosphere, total reflection occurs at an atmosphere/semiconductor layer interface to prevent a considerable portion of light generated in an active layer from escaping to the outside. Thus, high light output may not be expected.

Therefore, it is necessary to allow the light to escape to the outside with minimal loss by preventing the occurrence of the total reflection by artificially forming a nanostructure at the atmosphere/semiconductor layer interface on the surface of the n-type semiconductor layer.

Accordingly, light extraction of the light-emitting diode is significantly improved by typically forming a pyramid-shaped nanostructure on the surface of the n-type semiconductor by wet etching the surface of the n-type semiconductor using a basic solution such as KOH and NaOH.

However, with respect to the method of forming a pyramid structure using wet etching, the formation of a protective layer for preventing damages to an n-type electrode, a conductive substrate, and a mesa structure of the light-emitting diode during the wet etching was not only required, but also it was technically difficult to uniformly form a large-area nanostructure by the wet etching.

As another method, light extraction of a light-emitting diode is significantly improved by forming a conical nanostructure by coating the surface of the n-type semiconductor with a circular nanostructure and then performing dry etching.

However, the method of coating a circular nanostructure may be difficult to uniformly coat a wide area with a single layer and may be difficult to repeatedly form the nanostructure.

### SUMMARY OF THE INVENTION

The present invention addresses the above-identified, and other problems associated with conventional methods and apparatuses.

An aspect of the invention provides a method of manufacturing a light-emitting diode using nanostructure transfer, which may widely coat a surface of the light-emitting diode with a spherical nanostructure in a single layer, and a light-emitting diode manufactured thereby.

Another aspect of the invention provides a method of manufacturing a light-emitting diode using nanostructure transfer, which may form a pattern, which is very effective in light extraction, by using the coated nanostructure, and a light-emitting diode manufactured thereby.

According to an embodiment of the invention, there is provided a method of manufacturing a light-emitting diode, in which a first semiconductor layer, an active layer, and a second semiconductor layer are formed, using nanostructure transfer including the steps of:

(a) coating a spherical nanostructure on a first substrate;

(b) transferring the nanostructure from the nanostructure-coated first substrate to a second substrate;

(c) transferring the nanostructure transferred to the second substrate to a second semiconductor layer; and

(d) forming an uneven portion by dry etching the second semiconductor layer using the nanostructure transferred to the second semiconductor layer as a mask.

The spherical nanostructure may include at least one oxide of SiO₂, ZnO, Al₂O₃, MgO, TiO₂, SnO₂, In₂O₃, and CuO.

The spherical nanostructure may include at least one organic compound of polystyrene, polymethyl methacrylate (PMMA), and polyvinyl alcohol (PVA).

The spherical nanostructure may have a diameter of 100 nm to 3 μm.

Two types or more of the spherical nanostructures having different diameters may be mixed.

The method may further include performing a surface treatment on the first substrate before the step (a).

The surface treatment of the first substrate may include at least one of a piranha treatment, an oxygen plasma treatment, and an ultraviolet ozone treatment.

The second substrate may include at least one compound of polydimethylsiloxane (PDMS), PMMA, polyimide, and polycarbonate.

A pressure may be applied in the step (b) and the step (C).

A temperature of 80° C. to 150° C. may be applied in the step (b) and the step (C).

The uneven portion may have a conical shape.

According to another embodiment of the invention, there is provided a light-emitting diode manufactured by any one of the above-described methods.

The light-emitting diode may be a vertical light-emitting diode in which an active layer and a second semiconductor layer are sequentially formed on a first semiconductor layer.

The first semiconductor layer and the second semiconductor layer may be formed of gallium nitride.

The second semiconductor layer may be an n-type layer having an N-face.

### BRIEF DESCRIPTION OF THE DRAWINGS

FIG. 1 is a flowchart illustrating a method of manufacturing a light-emitting diode using nanostructure transfer according to an embodiment of the invention;

FIGS. 2 to 9 illustrate manufacturing processes of the light-emitting diode illustrated in FIG. 1;

FIG. 10 is scanning electron microscope (SEM) images of spherical nanostructures coated on a second semiconductor layer in FIG. 1 according to their diameters; and

FIG. 11 is SEM images of nanostructures which are formed by dry etching of the spherical nanostructures having different diameters illustrated in FIG. 10.

### DETAILED DESCRIPTION OF THE EXEMPLARY EMBODIMENTS

Hereinafter, the invention will be described in more detail based on preferred embodiments of the invention. However, the following embodiments are merely provided to allow for a clearer understanding of the invention, and the scope of the invention is not limited thereto.

In the invention, the expression “spherical” is used as a meaning including one with a seemingly round shape as well as a mathematical definition of a sphere, i.e., a three-dimensional shape composed of all points that are at the same distance from a point.

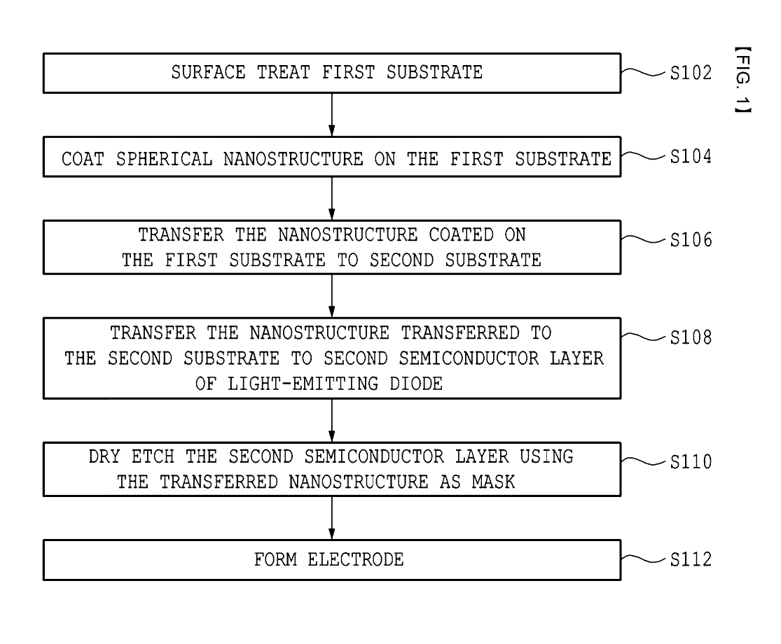

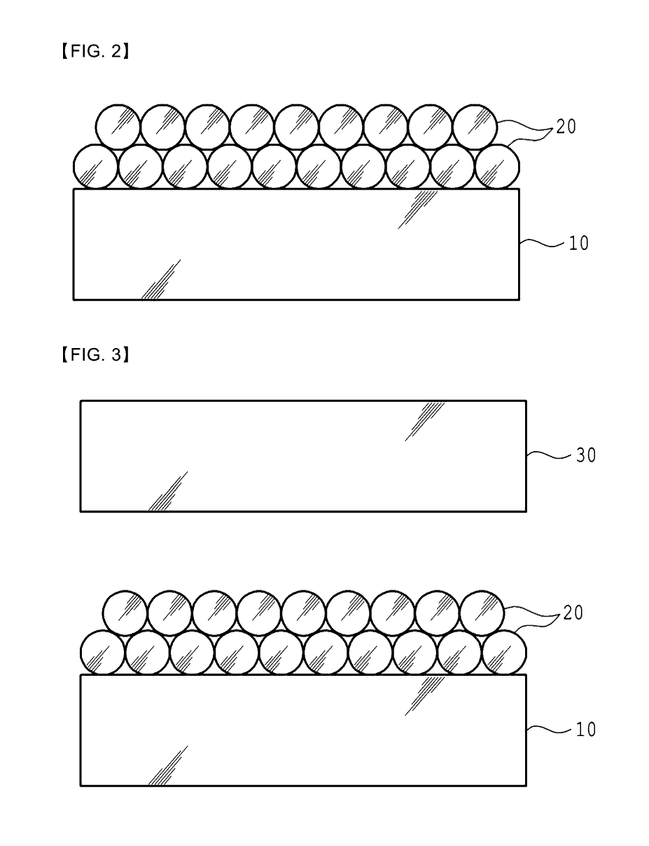

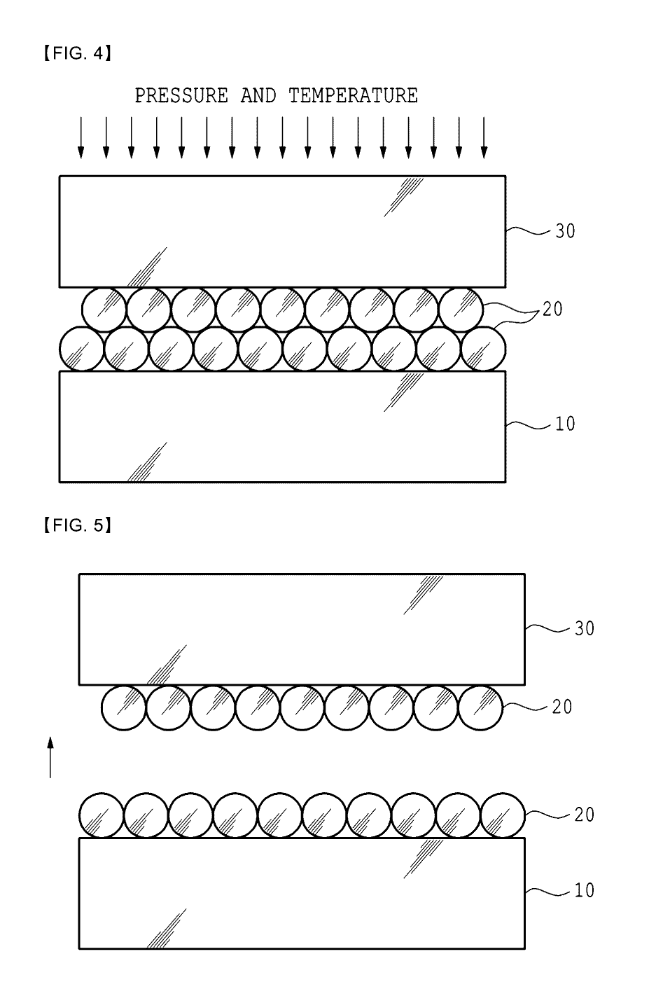

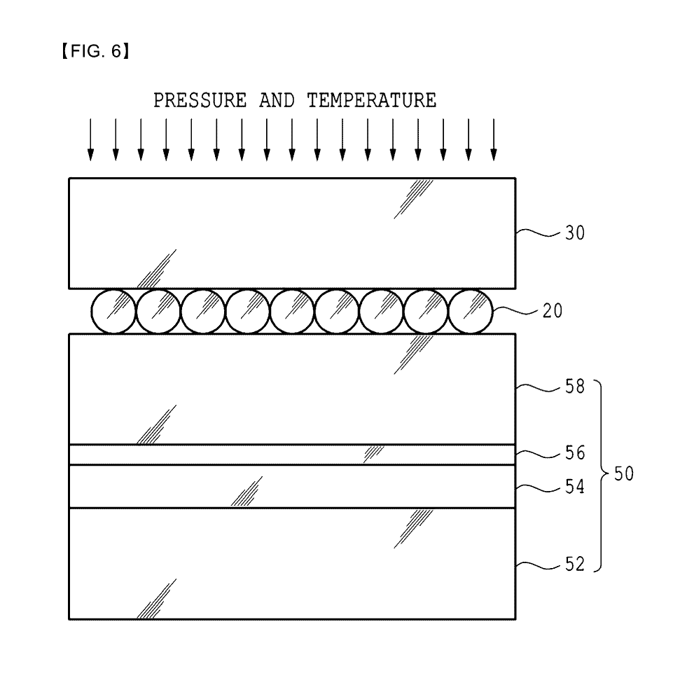

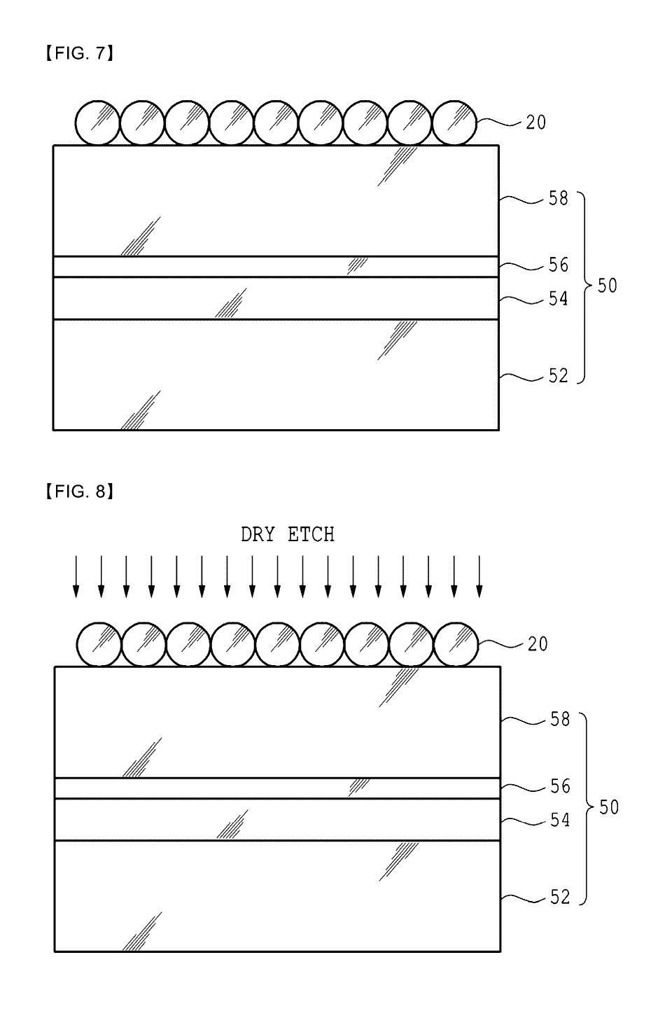

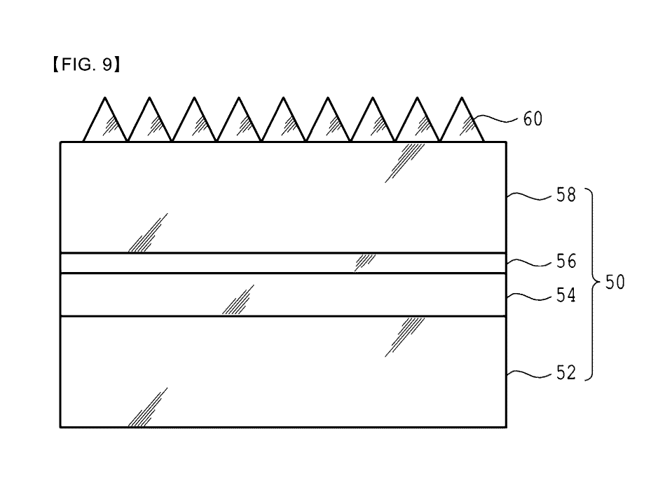

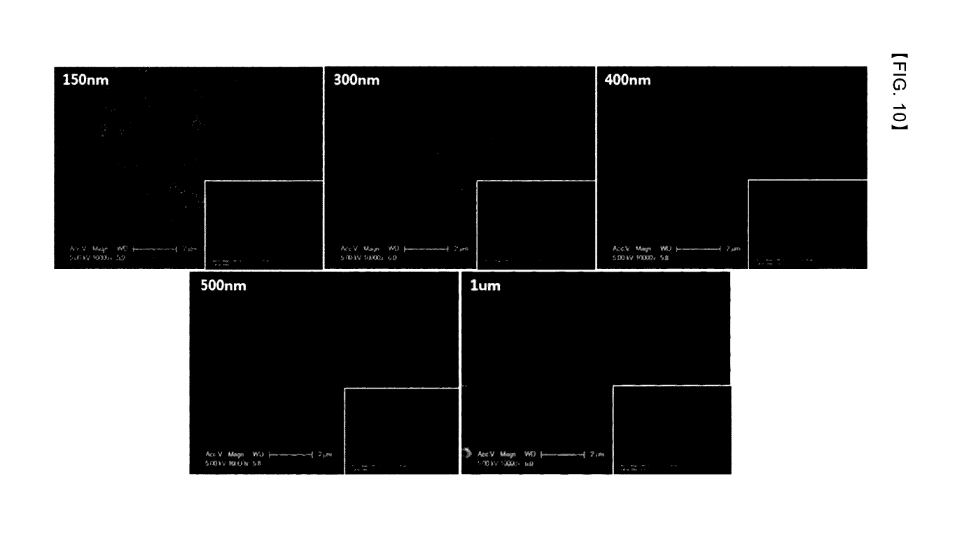

FIG. 1 is a flowchart illustrating a method of manufacturing a light-emitting diode using nanostructure transfer according to an embodiment of the invention, and FIGS. 2 to 9 illustrate manufacturing processes of the light-emitting diode illustrated in FIG. 1.

First, as illustrated in FIGS. 1 and 2, spherical nanostructures 20 are disposed on a surface of a first substrate 10 using, for example, a spin coater, and spin coating is then performed (S104).

In this case, the spherical nanostructures 20 may be formed of an oxide such as silica (SiO₂), ZnO, Al₂O₃, MgO, TiO₂, SnO₂, In₂O₃, and CuO.

Also, the spherical nanostructures 20 may be formed of an organic compound such as polystyrene, polymethyl methacrylate (PMMA), and polyvinyl alcohol (PVA).

Furthermore, the spherical nanostructures 20 may have a diameter of 100 nm to 3 μm.

In a case in which the diameter of the spherical nanostructures 20 is less than 100 nm, since cohesion between the nanostructures is increased, the spherical nanostructures 20 are difficult to be formed, and, in a case in which the diameter of the spherical nanostructures 20 is greater than 3 μm, since a size of a pattern after dry etching, as a subsequent process, is excessively large, a second semiconductor layer may lose its function as a semiconductor.

Also, two types or more of the spherical nanostructures 20 having different diameters may be mixed.

Furthermore, before the coating of the spherical nanostructures 20 on the first substrate 10, the first substrate 10 may be surface-treated in order that the surface of the first substrate 10 is hydrophilically modified to be uniformly coated with the spherical nanostructures 20 (S102).

In this case, the surface treatment of the first substrate 10, for example, may include at least one of a piranha treatment, an oxygen plasma treatment, and an ultraviolet ozone treatment.

Next, as illustrate in FIGS. 1 and 3 to 5, a second substrate 30 for transfer is disposed on the first substrate coated with the spherical nanostructures 20 and the nanostructures 20 are transferred to the second substrate 30 by applying a pressure of 0.1×10⁵ pa to 1×10⁵ pa while applying a predetermined temperature (S106).

The second substrate 30 may be formed of a softer material than the first substrate 10, for example, at least one compound of polydimethylsiloxane (PDMS), PMMA, polyimide, and polycarbonate.

The predetermined temperature may be in a range of 80° C. to 150° C.

That is, in a case in which the predetermined temperature is less than 80° C., since it is difficult to break a bond between the spherical nanostructures 20 and the first substrate 10, partial transfer of the spherical nanostructures 20 may not be smoothly performed, and, in a case in which the predetermined temperature is greater than 150° C., the second substrate 30 formed of a plastic material, such as PDMS, may be deformed.

The spherical nanostructures 20 may be uniformly formed in a single layer on the second substrate 30 by the transfer.

Next, as illustrate in FIGS. 1, 6, and 7, the second substrate 30 to which the spherical nanostructures 20 are transferred, for example, is disposed on a second semiconductor layer 58 of a vertical light-emitting diode 50 and the nanostructures 20 are transferred to the second semiconductor layer 58 by applying a pressure of 0.1×10⁵ pa to 1×10⁵ pa while applying a predetermined temperature (S108).

The vertical light-emitting diode 50 is formed by sequentially forming a first semiconductor layer 54, an active layer 56, and the second semiconductor layer 58 on a conductive substrate 52.

Also, the first semiconductor layer 54 and the second semiconductor layer 58 may be formed of gallium nitride (GaN).

The predetermined temperature during the transfer may be in a range of 80° C. to 150° C. as described above.

The spherical nanostructures 20 may be uniformly formed in a single layer on the second semiconductor layer 58 formed of gallium nitride by the transfer.

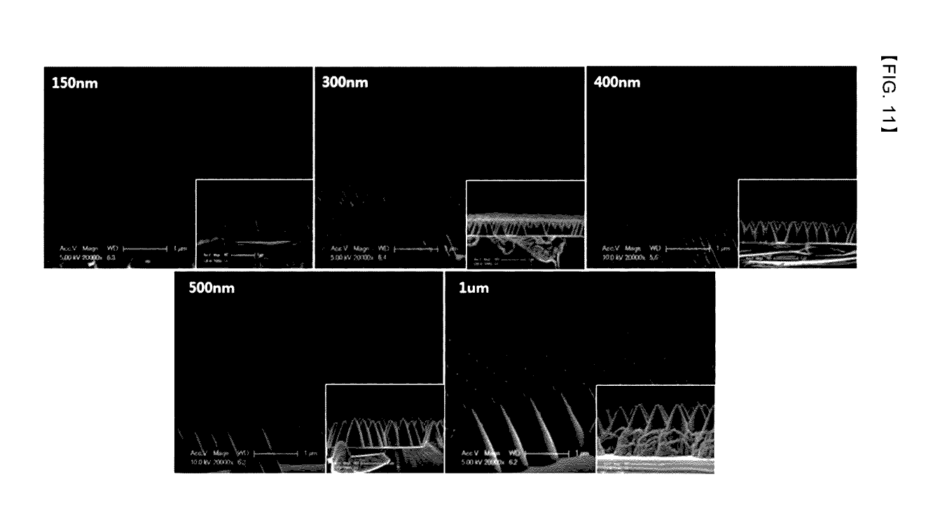

FIG. 10 is scanning electron microscope (SEM) images of the spherical nanostructures coated on the second semiconductor layer in FIG. 1 according to their diameters, wherein it may be understood that the nanostructures having a diameter of 150 nm, 300 nm, 400 nm, 500 nm, and 1 μm are uniformly formed.

Although the transfer of the nanostructures 20 to the second semiconductor layer 58 of the vertical light-emitting diode 50 has been described as an example in the above description, the nanostructures 20 may be transferred to a semiconductor layer of a horizontal light-emitting diode.

Next, as illustrate in FIGS. 1, 8, and 9, the surface of the second semiconductor layer 58 is dry-etched using the spherical nanostructures 20 coated on the second semiconductor layer 58 as a mask to obtain an uneven portion (S110).

That is, the surface of the nitride semiconductor coated with the spherical nanostructures 20, i.e., the surface of the second semiconductor layer 58 is dry-etched using an inductive coupled plasma (ICP) etcher to form an uneven portion, for example, conical nanostructures 60.

FIG. 11 is SEM images of nanostructures which are formed by dry etching of the spherical nanostructures having different diameters illustrated in FIG. 10, wherein it may be understood that the conical nanostructures 60 are formed.

### EXAMPLE

First, indium tin oxide (ITO)-coated glass was used as a first substrate 10 on which spherical nanostructures 20 are coated.

In this case, the first substrate 10 was surface-treated in order for the first substrate 10 to be well coated with the spherical nanostructures 20 and to have hydrophilicity through an ultraviolet ozone (UVO) treatment (S102).

Spherical nanostructures formed of silica (SiO₂) were coated on the first substrate 10 using a spin coating method (S104), and the spherical nanostructures 20 were transferred to a second substrate 30 formed of PDMS while applying temperature and pressure (S106).

The nanostructures 20 transferred to the second substrate 30 formed of PDMS were transferred to a second semiconductor layer 58 of a vertical light-emitting diode 50 while applying temperature and pressure (S108), and dry etching is performed by an ICP etcher using the transferred spherical nanostructures 20 as a mask to form conical nanostructures 60 (S110).

In the invention, the second semiconductor layer was an n-type layer having an N face.

Finally, in an electrode forming process (S112), a pattern was formed by using a known lithography method and an n-type electrode was then formed by using an electron beam deposition of Cr/Au.

With respect to a typical semiconductor substrate having a smooth surface, since a refractive index (n˜2.5) of a gallium nitride semiconductor substrate and a refractive index (n=1) of the atmosphere are significantly different, a critical angle for total reflection is only 23.5°.

Accordingly, since light generated in the semiconductor may not escape to the outside and may disappear in the semiconductor, light extraction efficiency may be low.

In contrast, according to an exemplary embodiment of the invention, since the conical nanostructures 60 were formed on the surface of the second semiconductor layer 58 to rapidly increase the probability of emitting the light generated in the semiconductor into the air, light extraction efficiency of the vertical light-emitting diode 50 may be significantly improved.

According to the exemplary embodiments of the invention, since light output may be increased by three times or more in comparison to a conventional vertical light-emitting diode having a flat surface of an n-type semiconductor and the same light extraction result as in wet etching, which is typically known to be the most effective in light extraction, may be obtained, it is suitable for a high-power light-emitting diode.

Also, it may be immediately applied to a manufacturing process of a gallium nitride-based light-emitting diode which is currently being widely used, and may be applied to a horizontal light-emitting diode structure as well as a vertical light-emitting diode structure.

Furthermore, since electron beam lithography patterning, in which manufacturing costs are high and it is difficult to apply to a large-area wafer process, is not used and various types of nanostructures may be formed by changing conditions of dry etching, application to a large area, reduction of the manufacturing costs, and reduction of process time may be obtained.

Although the technical spirit of the invention has been described in conjunction with the accompanying drawings, this description is intended to describe the preferred embodiments of the invention for illustrative purposes only, and is not intended to limit the invention. Furthermore, it will be apparent to those skilled in the art that various variations and modifications are possible within a range that does not depart from the scope of the technical spirit of the invention.

1. A method of manufacturing a light-emitting diode, in which a first semiconductor layer, an active layer, and a second semiconductor layer are formed, using nanostructure transfer, the method comprising steps of:
(a) coating a spherical nanostructure on a first substrate;
(b) transferring the nanostructure from the nanostructure-coated first substrate to a second substrate;
(c) transferring the nanostructure transferred to the second substrate to a second semiconductor layer; and
(d) forming an uneven portion by dry etching the second semiconductor layer using the nanostructure transferred to the second semiconductor layer as a mask.

2. The method according to claim 1,
wherein the spherical nanostructure comprises at least one oxide of SiO₂, ZnO, Al₂O₃, MgO, TiO₂, SnO₂, In₂O₃, and CuO.

3. The method according to claim 1,
wherein the spherical nanostructure comprises at least one organic compound of polystyrene, polymethyl methacrylate (PMMA), and polyvinyl alcohol (PVA).

4. The method according to claim 1,
wherein the spherical nanostructure has a diameter of 100 nm to 3 μm.

5. The method according to claim 1,
wherein two types or more of the spherical nanostructures having different diameters are mixed.

6. The method according to claim 1,
further comprising performing a surface treatment on the first substrate before the step (a).

7. The method according to claim 6,
wherein the surface treatment of the first substrate comprises at least one of a piranha treatment, an oxygen plasma treatment, and an ultraviolet ozone treatment.

8. The method according to claim 1,
wherein the second substrate comprises at least one compound of polydimethylsiloxane (PDMS), PMMA, polyimide, and polycarbonate.

9. The method according to claim 1,
wherein a pressure is applied in the step (b) and the step (C).

10. The method according to claim 1,
wherein a temperature of 80° C. to 150° C. is applied in the step (b) and the step (C).

11. The method according to claim 1,
wherein the uneven portion has a conical shape.

12. A light-emitting diode manufactured by claim 1.

13. The light-emitting diode according to claim 12,
wherein the light-emitting diode is a vertical light-emitting diode in which an active layer and a second semiconductor layer are sequentially formed on a first semiconductor layer.

14. The light-emitting diode according to claim 13,
wherein the first semiconductor layer and the second semiconductor layer are formed of gallium nitride.

15. The method according to claim 13,
wherein the second semiconductor layer is an n-type layer having an N-face.

16. A light-emitting diode manufactured by claim 2.

17. A light-emitting diode manufactured by claim 3.

18. A light-emitting diode manufactured by claim 4.

19. A light-emitting diode manufactured by claim 5.

20. A light-emitting diode manufactured by claim 6.
